(19) United States
(12) Patent Application Publication
(10) Pub. No.: US 2012/0263887 A1
(43) Pub. Date: Oct. 18, 2012

(54) TECHNIQUE AND APPARATUS FOR ION-ASSISTED ATOMIC LAYER DEPOSITION

(75) Inventors: George D. Papasouliotis, North Andover, MA (US); Ludovic Godet, Boston, MA (US)

(73) Assignee: VARIAN SEMICONDUCTOR EQUIPMENT ASSOCIATES, INC., Gloucester, MA (US)

(21) Appl. No.: 13/085,615

(22) Filed: Apr. 13, 2011

(51) Int. Cl. C23C 16/50; C23C 16/52; C23C 16/46; C23C 16/02; C23C 16/44; C23C 16/458

(52) U.S. Cl. 427/569; 118/702

(57) ABSTRACT

An apparatus for depositing a coating may comprise a first processing chamber configured to deposit a first reactant as a reactant layer on a substrate during a first time period. A second processing chamber may be configured to direct ions incident on the substrate at a second time and configured to deposit a second reactant on the substrate during a second time period, wherein the second reactant is configured to react with the reactant layer.

### FIELD

This invention relates to the coating of substrates and, more particularly, to a method and apparatus for producing conformal films.

### BACKGROUND

Atomic layer deposition (ALD) is a deposition method that is related to chemical vapor deposition (CVD). In ALD, typically two separate reactions (half-cycles) using separate precursors are conducted sequentially to complete a single full deposition cycle that deposits a fixed amount of material. After each half-cycle, a fixed amount of reactive species supplied by a first precursor remain on the substrate surface. Ideally, a single monolayer of a first species may be produced after a first half cycle. Each species of the monolayer of first species may be reacted with species of the second precursor supplied in the next half cycle. In each half-cycle, subsequent to supplying the reactive species, a purge can be performed to remove any unreacted species of the depositing material. The total amount of material reacted in a cycle is thus equivalent to a monolayer of each reactant. In this manner, each cycle may produce the same amount of material as any other cycle. Thus, within a wide process window, the total thickness of a deposit only depends on the number of cycles performed, where layers as thin as tenths of Angstroms can be controllably produced in any given cycle.

The self-limiting nature of ALD and the ability to produce extremely thin layers has engendered widespread efforts to develop ALD for microelectronics and related applications, where very thin layers may be desired. ALD has been used to deposit several types of thin films, including various oxides (e.g. Al₂O₃, TiO₂, SnO₂, ZnO, HfO₂), metal nitrides (e.g. TiN, TaN, WN, NbN), metals (e.g. Ru, Ir, Pt), and metal sulfides (e.g. ZnS).

Moreover, because ALD is a surface reaction-dominated process, it also affords the potential of producing conformal coatings in substrates having extensive topography, to the extent that depositing species can be reacted on all regions of a non-planar substrate surface.

However, several challenges exist to the widespread adoption of ALD. Because many potential applications require low substrate temperatures and because purge steps need to be applied during each cycle, the ALD growth rate may be extremely slow under the required deposition conditions. The low temperature requirement may also result in contamination of films or poor film density due to residual incorporation of unwanted precursor atoms and the limited mobility of adsorbed atoms at low substrate temperatures.

In addition, achieving conformal film deposition of ALD films at low substrate temperatures remains a challenge, in part because the low temperatures may be insufficient to fully react the two reactants. In other cases where an elemental film needs to be deposited the low temperature operation may cause slow surface decomposition of the single precursor reactant. To accelerate film deposition at low temperatures, plasma assisted ALD techniques have been developed. Several variations of plasma assisted ALD techniques have been developed in which the degree of ion exposure to the substrate differs. In direct plasma ALD, the substrate may be placed in direct contact with a plasma, such as a diode-type plasma. In this configuration, a high density of ions may impinge at a normal angle of incidence to the substrate. In another variation, remote plasma ALD, a plasma may be created remotely and ions may impinge on a substrate placed at a distance from the main plasma. Ions, energetic neutrals, and radicals may strike the substrate, with the ion density generally less than in direct plasma ALD. An extreme version of remote plasma ALD, sometimes termed radical enhanced ALD, involves creating a plasma remotely from a substrate, in which few if any ions contact the substrate, but rather gas phase radicals created by the plasma impinge on the substrate.

In any of these plasma assisted techniques, a plasma may supply sufficient energy to activate species from a first precursor (reactant) that are disposed on a substrate surface so that the activated species react with depositing species from a second reactant. However, reaction of the first and second reactants may be non-uniform across a substrate surface that has surface relief features. Since ions from conventional plasmas impinge upon a substrate with a high degree of directionality, the ions may fail to reach certain areas of substrates, such as trench corners or sidewalls of relief features, thereby limiting the reactivity of such regions.

FIGS. 1a-d depict film formation on a substrate 100 using a conventional plasma assisted ALD process. In a first step depicted at FIG. 1a, species of a first reactant 12 are provided on relief features of the substrate 100. As the species condense, they may have sufficient mobility to coat the entire surface of substrate 100. A sufficient amount of first reactant is typically provided so that the surface may become saturated, forming a continuous layer 112 containing the first reactant, as illustrated at FIG. 1b. Any excess first reactant may be purged before a second reactant is introduced. As depicted at FIG. 1c, in plasma assisted ALD, a plasma can provide species such as ions 18 during introduction of a second reactant to the film substrate. The ions generally impinge on the substrate 100 in a parallel fashion that is normal to a plane of the substrate, shown as horizontal in the figures. The horizontal surfaces may intercept most or all of the ion flux, such that reaction of the first reactant with the second reactant is promoted on the horizontal surfaces. However, the sidewalls 16 of relief features do not intercept ion flux. Therefore, the ions 18 may fail to promote the reaction of a second reactant (which may be partially or wholly included in the ion flux and is not separately shown) and first reactant 12 disposed on the substrate sidewall 16. Subsequently, as depicted at FIG. 3d, the system may be purged of any excess second reactant and any unreacted first reactant, leaving a reacted coating 14 that constitutes a product of the reaction of first and second reactants.

Because less reaction of first and second reactants may occur on sidewall 16, the resulting reacted coating 14 may be non-uniform (non-conformal) and may exhibit a much greater coating thickness on surfaces of particular orientations (in this case, horizontal) as opposed to other orientations. Accordingly, known plasma assisted ALD processes may provide non-conformal coatings in substrates having surface relief features, such as high aspect ratio trenches or structures having steeply sloped sidewalls.

In view of the above, it will be apparent that improvements in ALD processes are needed.

### SUMMARY

In one embodiment, an apparatus for depositing a coating includes a first processing chamber configured to deposit a first reactant as a reactant layer on a substrate during a first time period and a second processing chamber configured to direct ions incident on the substrate over a range of angles, and configured to deposit a second reactant on the substrate during a second time period, said second reactant configured to react with said reactant layer.

In another embodiment, a method of depositing a conformal film on a substrate comprises depositing a first reactant as a reactant layer on the substrate at a first time, reacting a second reactant on the on the reactant layer, and exposing the reactant layer to ions that are incident on the substrate over a range of angles with respect to a plane of the substrate.

### BRIEF DESCRIPTION OF THE DRAWINGS

For a better understanding of the present disclosure, reference is made to the accompanying drawings, which are incorporated herein by reference and in which:

FIGS. 1a-d depict a known ALD process;

FIGS. 2a and 2b depict an ALD apparatus consistent with an embodiment of the disclosure;

FIG. 3 depicts a cross-section of an exemplary extraction plate;

FIGS. 4a-d depict cross-sections of a substrate feature during an ALD process consistent with an embodiment of the disclosure;

FIG. 5 depicts an ALD apparatus consistent with another embodiment of the disclosure; and

FIG. 6 depicts exemplary steps in a method consistent with another embodiment.

### DETAILED DESCRIPTION

Embodiments disclosed herein provide improved film deposition apparatus and processes, and in particular improved ALD processes. In various embodiments, an ALD apparatus includes a processing chamber for providing a first reactant to a substrate and a processing chamber for providing a second reactant to a substrate. In some embodiments the processing chambers for first and second reactants are different chambers. According to various embodiments, the first and second reactants may be provided in an ALD process sequence wherein one or more ALD deposition cycles are performed to form respective one or more layers of the film to be grown on the substrate. Each deposition cycle may comprise a first exposure of the substrate to a first reactant that saturates a surface of the substrate, followed by a purge of excess first reactant, and a second exposure to a second reactant of the substrate having the saturated first reactant disposed thereon.

In various embodiments, the second reactant may comprise ions that impinge upon the substrate over a range of angles. The ions may supply sufficient energy to facilitate reaction of first and second reactants to form a desired product layer. In various embodiments, the desired product layer may be a layer that comprises an elemental material, an oxide, a nitride, or other material. Because the second reactant may be provided as ions or together with ions incident on the substrate over a range of angles, the present embodiments facilitate conformal coating of substrates having trenches and other steeply sloped topology, as detailed below.

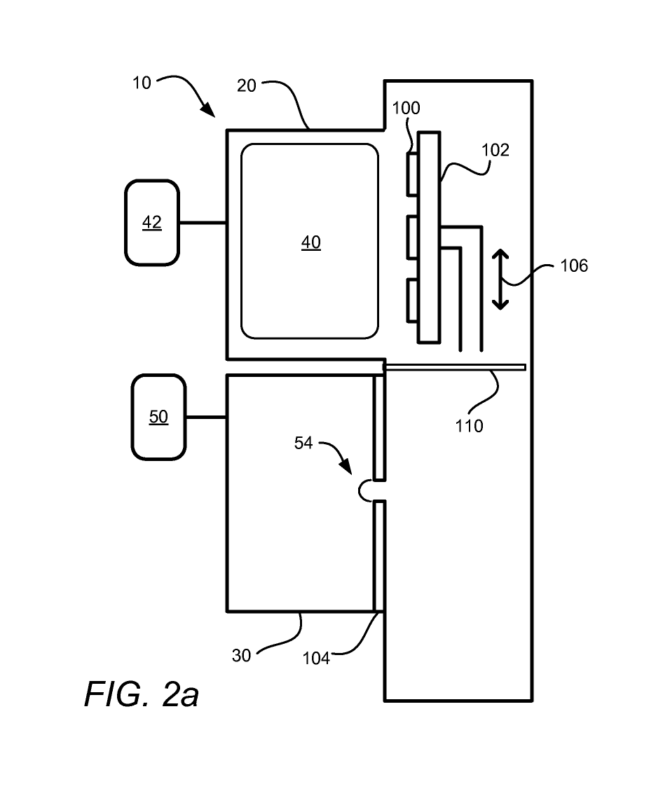

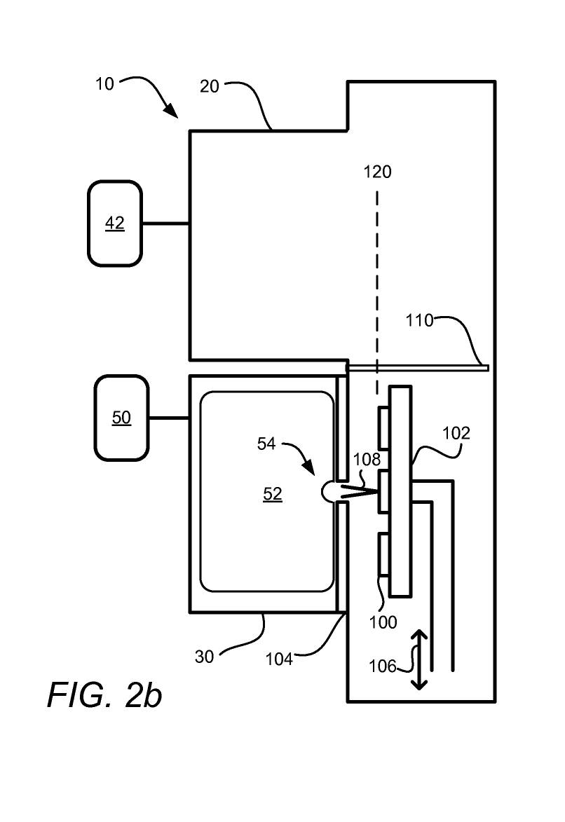

FIGS. 2a and 2b depict an ALD apparatus 10 consistent with an embodiment of the disclosure. The ALD apparatus includes first and second processing chambers 20 and 30, respectively, which may be used for providing respective first and second precursors (reactants) in an ALD deposition process. ALD apparatus 10 includes a substrate holder 102 for holding a single substrate or multiple substrates 100.

The substrates 100 may be arranged in an array or matrix that is N substrates 100 wide and N substrates 100 long (where the “N” variable in the width dimension can be different from that in the length dimension). In FIGS. 2a,b a matrix of 1×3 substrates is illustrated. The substrate holder 102, which is arranged in a vertical orientation, may use electrostatic clamping, mechanical clamping, or a combination of electrostatic and mechanical clamping to retain the substrates 100. The substrates 100 may be scanned using the substrate holder 102. In the embodiment illustrated, the substrate holder 102 can scan in the direction 106 such that substrates 100 may be positioned proximate either the first processing chamber 20 (FIG. 2a) or the second processing chamber 30 (FIG. 2b) for exposure to respective first and second precursors. In various embodiments, the substrate holder 102 may be moved between positions proximate chamber 20 and chamber 30 using a linear translation or a rotational movement along an arc.

The chamber 20 may be arranged to provide a first precursor (reactant) to a substrate 100 in a fixed dose using precursor source 42, which fills chamber 20. In some embodiments, chamber 20 may also provide a plasma 40 as discussed further below. As illustrated, an isolator 110 is provided to isolate chamber 20 from chamber 30 during exposure of the substrate to a precursor source 42. In some embodiments, a gas curtain may function as an isolator, while in other embodiments, vacuum or a solid barrier may be used.

In order to provide a fixed dose of a first reactant to the substrate 100 while substrate holder 102 is positioned proximate chamber 20, the chamber 20 may be isolated from any pump (not shown) used to evacuate the chamber.

In various embodiments, the second processing chamber 30 is arranged to provide a second reactant to a substrate 100 with the aid of ions 108. The ions 108 may constitute at least a part of the second reactant to be reacted with the first reactant that is in place on substrate 100 when ions 108 are provided. In some embodiments, at least a portion of the ions 108 are inert species that do not condense within a film to be formed on substrate 100. In some embodiments, after exposure to a first reactant in chamber 20 (FIG. 2a), substrate holder 102 is moved to a position proximate chamber 30 (FIG. 2b), after which a plasma source 50 is used to produce a plasma 52, from which ions 108 are extracted. As detailed below, in various embodiments the ions are extracted through an extraction plate, such as extraction plate 104, which provides ions over a range of angles of incidence to substrate(s) 100 during the exposure to the second reactant. By virtue of providing ions over a range of angles with respect to a substrate surface, the reactivity of the second reactant and first reactant may be enhanced on surfaces of substrate features that may be recessed, or may form an angle with respect to a plane 120 of the substrate. In this manner, the reaction of first and second reactants may be more uniform over all substrate surface regions, including on substrate features having deep recesses or other non-planar features. This may result in formation of a more conformal product layer, that is, a layer of more uniform thickness on all substrate surfaces, regardless of surface orientation.

In either or both processing chambers 20, 30, the volume of enclosures in which the substrates reside may be kept small to reduce the amount of reactant needed for saturating the substrate surface during each exposure, as well as the time required to evacuate reactor chambers between processes. In some embodiments, the chamber walls comprise surfaces that do not adsorb reactants to minimize film buildup on chamber walls. In particular, organic materials may be minimized to prevent reactions with typical precursors that may be employed to deposit films, such as nitrides.

Consistent with some embodiments, reactants are supplied in a continuous flow mode to a given chamber, or, alternatively, by pressurizing and discharging an enclosure. In either case, a metered amount of reactant may be delivered to the system during a cycle of exposure to a reactant.

In various embodiments, the substrate holder 102 is equipped with a heater (not shown) or is heated by an external heating source, such as radiation lamps. The substrate heater may be employed to improve film quality of ALD films, as well as improving conformality.

Consistent with embodiments of the disclosure, the plasma source 50 may be a capacitively coupled source, inductively coupled source, a microwave source, a helicon source, inductively heated cathode source, or other plasma source known to those of skill in the art. In addition, the source may be arranged in direct view of the substrate or may be more remotely situated with respect to substrates 100 during processing.

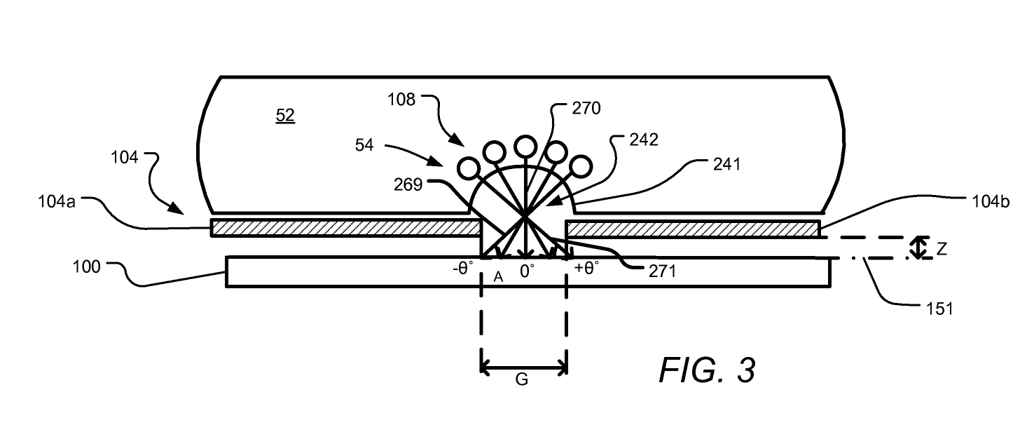

In order to provide ions over a range of angles at substrate 100, an extraction plate 104 may be positioned proximate a region where plasma 52 forms. FIG. 3 is a cross-sectional view of details of an extraction plate 104 within a plasma system consistent with one embodiment. For ease of illustration, the extraction plate 104 is depicted in a horizontal configuration, but may be arranged in a vertical configuration as shown in FIGS. 2. The extraction plate 104 is arranged proximate a plasma 52 that places the extraction plate within a plasma sheath 242. Extraction plate 104 is operable to modify an electric field within the plasma sheath 242 to control a shape of a boundary 241 between plasma 52 and the plasma sheath 242, and may produce a curved boundary as shown. Accordingly, as a result of the curvature of the plasma sheath boundary 241, and because the ions 108 may exit the plasma 52 in a direction generally orthogonal to the sheath boundary, the ions may enter the plasma sheath 242 over a range of angles and then strike the substrate 100 at a large range of incident angles, as illustrated.

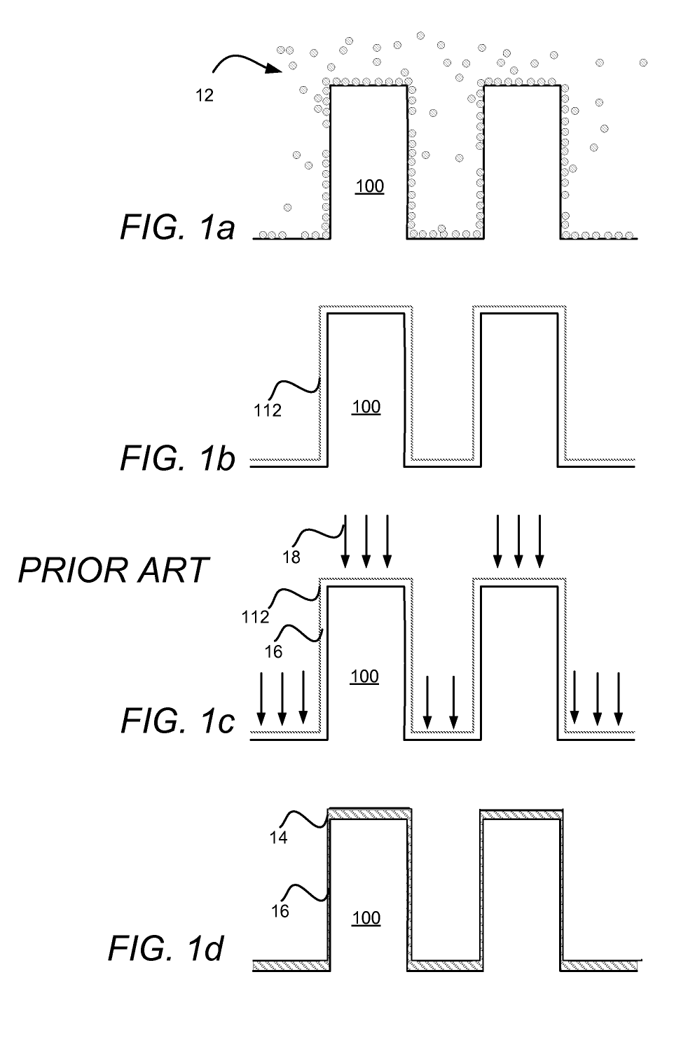

The plasma 52 may be generated as described above with respect to FIG. 1. Extraction plate 104 may be a unitary plate having a slot between regions 104a and 104b or may be a set of panels 104a and 104b defining an aperture there between having a horizontal spacing (G). The panels 104a,b may be an insulator, semiconductor, or conductor. In various embodiments, the extraction plate 104 may include a multiplicity of apertures (not shown). Extraction plate 104 may be positioned at a vertical spacing (Z) above the plane 120 defined by the front surface of the substrate 100. The extraction plate 104 may be powered (using DC or RF power) or may be floating in some embodiments.

Ions 108 may be attracted from the plasma 52 across the plasma sheath 242 by different mechanisms. In one instance, the substrate 100 is biased to attract ions 108 from the plasma 52 across the plasma sheath 242. Advantageously, the extraction plate (the term “extraction plate” may be used hereinafter to refer to a unitary plate or a plurality of plates that define at least one aperture) 104 modifies the electric field within the plasma sheath 242 to control a shape of the boundary 241 between the plasma 52 and the plasma sheath 242. The boundary 241 between the plasma 52 and the plasma sheath 242 may have a convex shape relative to the plane 151 in one instance. When the substrate 100 is biased, for example, the ions 108 are attracted across the plasma sheath 242 through the aperture 54 at a large range of incident angles. For instance, ions following trajectory path 271 may strike the substrate 100 at an angle of +θ° relative to the plane 151. Ions following trajectory path 270 may strike the substrate 100 at about an angle of −θ° relative to the same plane 151. Ions following trajectory path 269 may strike the substrate 100 at an angle of −θ° relative to the plane 151. Accordingly, the range of incident angles may be between ++θ° and −θ° centered about 0°. In addition, some ion trajectories such as paths 269 and 271 may cross each other. Depending on a number of factors including, but not limited to, the horizontal spacing (G) that defines one dimension of the aperture 54, the vertical spacing (Z) of the extraction plate above the plane 151, the dielectric constant of the extraction plate, or other process parameters of the plasma 52, the range of incident angles (θ) may be between +60° and −60° centered about 0°. Thus, under some conditions ions 108 may strike substrate 100 over a range of angles between +60° and −60° while under other conditions the ions 108 may strike substrate 100 over a narrower range of angles, such as between +30° and −30.°

In various embodiments of an ALD system, such as system 10, the extraction plate 104 may be configured to tailor the distribution of incidence angles of ions on substrate 100 when a reactant in an ALD process is provided to the substrate surface. As noted above, in some cases ions 108 may comprise different species, such as inert gas ions and nitrogen-containing ions, which may be employed to form nitride materials. Because the ions 108 impinge on substrate 100 over a range of angles, the ions may effectively strike areas of relief features in a substrate that are difficult to reach using conventional plasma assisted ALD. Thereby, the ions more effectively promote reaction of first and second reactants over all surface regions of relief features.

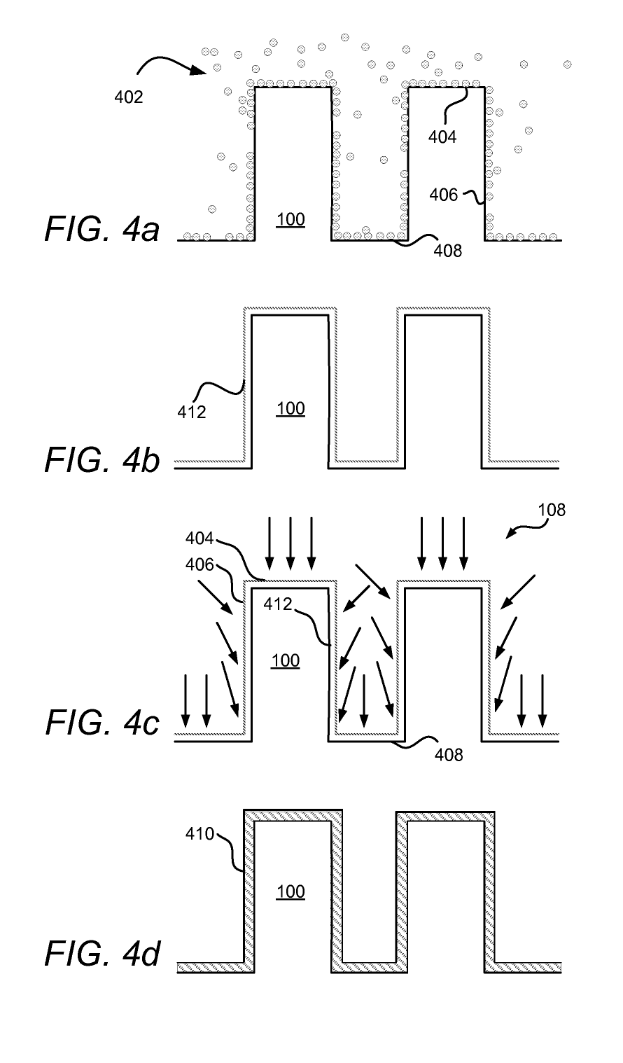

FIGS. 4a-d depict a conformal ion-assisted ALD film formation process consistent with embodiments of the present disclosure. For the purposes of illustration, the ion-assisted ALD process may be described with respect to an exemplary material system, silicon nitride. However, the processes depicted and disclosed herein apply to a variety of materials including elemental films, metallic compounds and insulating compounds (oxides, nitrides, oxynitrides, etc.), and alloys, among others. In a process depicted at FIG. 4a, species of a first reactant 402 are provided on relief features of the substrate 100. In some embodiments, the first reactant may be a silicon-containing species, such as SiH₄, Si₂H₆, SiH₂Cl, SiCl₄, or other appropriate reactant known to those of skill in the art. A metered amount of reactant may be provided so that the amount of first reactant 402 present in the reaction chamber is sufficient or in excess of that required to coat the desired substrate surfaces with a monolayer of first reactant 402. The substrate 100 may be heated during this process, for example, to a temperature in excess of about 30° C. The depositing species, such as silane species, may have sufficient mobility to cover the entire surface of the relief features including top surfaces 404, sidewalls 406 and trenches 408. After sufficient substrate 100 is exposed to sufficient species of first reactant 402, excess reactant may be purged from a chamber containing the substrate. In some embodiments, during exposure of the first reactant 402 to substrate 100 a carrier gas, such as an inert gas (not shown), is also provided in the reaction ambient surrounding substrate 100. The carrier gas, or another gas, may be used as a purging gas to facilitate removal of excess first reactant 402.

When the first reactant 402 covers the surface of substrate 100, a conformal monolayer of reactant layer 412 remains on substrate 100 after the purging of excess first reactant 402, as depicted in FIG. 4b. At this stage, the reactant layer 412 contains one component of material to be incorporated into the desired film, such as silicon. In addition, the reactant layer 412 may include undesired material, such as hydrogen, which may remain bonded to the silicon atoms.

In a subsequent process depicted at FIG. 4c, the substrate 100, including reactant layer 412, is exposed to ions 108 that are incident on the substrate over a range of angles of incidence. The ions 108 may be provided in conjunction with exposure of substrate 100 to a second reactant (not separately depicted). In some embodiments the substrate temperature is elevated above room temperature when the second reactant is introduced. In various embodiments, at least a portion of the second reactant is provided as ions 108. For example, ions 108 may be derived from gaseous N₂ and/or NH₃ species that are supplied into a plasma. The ionized nitrogen-containing species may then be extracted through an aperture and reacted with a monolayer formed from a first reactant 402 that comprises silicon-containing species, thereby forming a SiNₓ compound. However, not all of the second reactant need be ionized, nor need all ions form part of the second reactant. For example, in some embodiments, ions 108 include inert gas ions that facilitate reaction of first and second reactants but are not designed to be incorporated in the resultant ALD layer. Such species include He, Ar, Xe, and Ne.

Because ions 108 are provided over a range of angles of incidence, the ions may reach regions of substrate 100 that are generally inaccessible to ions in conventional plasma assisted ALD. Thus, in addition to striking top surfaces 404, and trenches 408, the ions also strike sidewalls 406. In so doing, the ions 108 may promote reaction of the second reactant (not separately shown) with reactant layer 412 throughout the surface of the relief features.

As depicted at FIG. 4d, after ions 108 strike the reactant layer 412, the resultant reaction between the first reactant and second reactant forms a reacted product layer 410 on substrate relief features. Since ion-aided reaction may take place on most or all regions of the substrate surface, a more uniform layer of reacted product layer 410 forms than in conventional plasma-assisted ALD.

In some embodiments of silicon nitride deposition, an excess of nitrogen species is provided to react with a silane-based monolayer (such as reactant layer 412) to form an SiNₓ monolayer (such as reacted product layer 410). The bombardment of the top surfaces 404, sidewalls 406, and trenches 408 with ions 108 may facilitate release of hydrogen from the silane monolayer and facilitate the reaction of the nitrogen-containing species (which may themselves by ions, neutrals and/or radicals) to form the product silicon nitride layer. After reaction of the second reactant with reactant layer 412, a purging of excess reactant and unwanted species may be performed using, for example, an inert gas.

Consistent with some embodiments, the different processes illustrated in FIGS. 4a-d represent one cycle of an ALD process, in which a single monolayer of product, such as SiNₓ, is formed. This cycle may be repeated to produce a conformal coating of a desired thickness that is composed of multiple reacted product layers 410. Because only one monolayer of conformal coating may form with each cycle, the present embodiments can thus be used to conveniently produce coatings of any desired thickness that is greater than or equal to about one monolayer of material.

In some embodiments, the film composition is varied from one ALD cycle to another cycle. Thus, a gradient in film composition and properties may be produced by changing one or more of the relative amounts of first and second reactants, the ion exposure, substrate temperature during a cycle, and post film-formation processing, among other factors.

Although elevated substrate temperature is employed in some embodiments of the process depicted in FIGS. 4a-d, the substrate temperature may be substantially lower than that generally employed in ALD processes that do not employ plasma or ion assistance. For example, a substrate temperature of 400° C. or less is employed in some embodiments. Because the ions 108 are provided over a range of angles, the present embodiments also promote conformal coatings on relief features at reduced temperatures.

In various embodiments, control of substrate temperature is employed to change the reactivity of reactants, the rate of removal of unwanted adsorbed material, and to alter other film properties of the reacted product layer 410.

Referring again to FIGS. 2, other operating parameters of an ALD system 10 may be tuned to facilitate ALD processes such as the reaction of reactants and the removal from the product layer of unwanted material, such as hydrogen. These operating parameters include plasma gas composition and plasma power used during the introduction of a second reactant, bias between substrate and plasma, scanning recipe for scanning a substrate with respect to an extraction plate, as well the aforementioned substrate temperature.

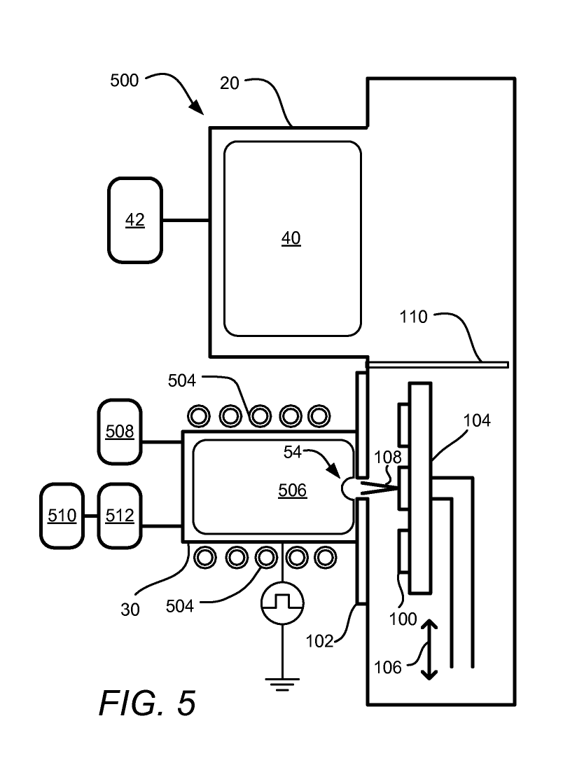

FIG. 5 depicts another embodiment of an ALD system 500 in which a plasma chamber 30 for introducing a second reactant is powered by an inductive source that drives coils 504 to generate an plasma 506. Gas species may be supplied from source 508, which may provide inert and/or reactive gases in various embodiments. Although not depicted, it will be understood that the inert gas species and reactive gas species may be provided from separate sources. An RF-generator 510 is provided to drive coils 504 using match network 512 to ignite plasma 506, which may include a combination of inert and non inert species. In addition to ions, neutral metastable species may be created in chamber 30 and impact substrate 100.

In order to tailor ion energy for ions 108, embodiments of the disclosure provide various ways to control the bias voltage between substrate 100 and plasma 506. In some embodiments, the plasma is set at ground potential and a negative bias may be applied to substrate holder 102 to attract positive ions. In other embodiments, the substrate holder 102 is grounded and plasma 506 may be maintained at a positive potential.

By varying the potential between substrate and plasma, the ion energy may be tailored according to desired properties of the ALD films. For example, referring also to FIG. 4c, at higher ion energy, the impact of ions 108 with substrate 100 may be more effective in removing material such as hydrogen from a reactant layer 412. The higher ion energy may also serve to densify the resultant film formed from reaction of reactant layer 412 with a second reactant. In the example of silicon nitride formation, nitrogen-containing neutrals or ions (derived, for example, from N₂ or NH₃) may be provided together with inert gas ions upon a silicon-containing reactant layer 412. The inert gas ions may act to reduce film porosity as well as remove hydrogen from reactant layer 412. Neutrals, such as metastable radicals, as well as ions, may also activate the reaction of the reactant layer 412 with condensing nitrogen-containing species. However, excess ion energy can lead to unwanted re-sputtering of condensed species of an SiNₓ layer, thereby reducing the film formation rate. Excess ion energy may also lead to an increase in film stress. It is known that varying ion energy of ions impinging on a film during growth often causes changes in film stress, such as changes in the level of tensile or compressive stress. Accordingly, for a given reactant layer 412 and ion species in chamber 30, an optimum ion energy may exist to facilitate formation of the desired SiNₓ film while keeping adverse side effects at an acceptable level.

In some embodiments, rather than providing a continuous flux of ions 108 during the introduction of the second reactant of an ALD process, the power of plasma 506 and/or bias voltage between substrate 100 and plasma 506 is provided in a pulsed fashion. In one example, if the voltage bias between plasma 506 and substrate 100 is provided in regular pulses, ions 108 may be attracted through aperture 54 only when a bias is applied. However, during the part of the pulse cycle in which no bias is applied other species, such as neutral gas species and metastable species (including radicals), may continue to impinge on substrate 100. Thus, tailoring of the duty cycle of applied substrate-plasma bias may affect film properties by changing the relative flux of ion bombardment compared to neutral species bombardment.

Consistent with other embodiments, the positioning of a substrate 100 is controlled to control conformality of an ALD film deposition process. As is apparent from FIGS. 2, 3 and 5, the aperture width G of aperture 54 may be small compared to a lateral size of a substrate to be coated. In such cases, in order to expose all desired portions of a given substrate to ions 108, scanning of substrate holder 102 along direction 106 is performed while plasma 52 is ignited. As evident from FIGS. 2a,b and FIG. 3, during scanning of any portion of a substrate with respect to a beam of ions 108, the angle of ions incident on that portion of the substrate may vary with time. Thus, when a substrate 100 passes proximate aperture 54, at an initial period ions 108 that strike point A of the substrate may arise from a first direction, while at a later instance the ions may strike point A from a different direction. The exposure of substrate relief features to ions 108 depicted in FIG. 4c thus may represent a sum of all the ion exposure during the period when the substrate 100 passes next to the aperture 54. As noted above, the exact distribution of angles of incidence of ions 108 may vary with the separation between extraction plate 104 and substrate 100, among other factors. In this manner, by varying the substrate-extraction plate separation, a greater or lesser amount of ions 108 is provided on sidewalls 406, thereby affording one measure of control of the conformality of an ion-assisted ALD deposition process. Moreover, as discussed above, a variety of other parameters may affect the incident angles of ions 108 to offer further adjustments to conformality.

For example, the plasma density proximate an extraction plate may vary according to the type of plasma source. Because plasma sheath dimension (thickness) is related to plasma density, the overall shape and position of boundary 241 may vary with plasma type. Accordingly, in some embodiments, adjustments to other parameters, such as aperture width G may be made to take into account different plasma densities in order to control the shape and position of the plasma sheath boundary and thereby control the distribution of ions incident on a patterned substrate.

The choice of an appropriate combination of parameters may be made according to a specific application and desired outcome. The ability to control the distribution of angles of ions 108 may be particularly helpful to tailor the ion assisted ALD process for different substrates. For example, the distribution of angles of ions 108 may be varied to account for changes in aspect ratio of surface relief features, such as trenches, fins in finFET devices, and other features. Thus, a higher aspect ratio relief feature may require a broader angular distribution of ions as compared to a lower aspect ratio feature.

Turning once more to FIGS. 2a,b in some embodiments, the system 10, including the chamber 20, is employed to preclean a substrate 100 before deposition of a first reactant. In particular embodiments, chamber 20 (or another chamber (not shown)) may be used as a plasma cleaning chamber and may be equipped with a plasma source (not shown) to generate a plasma, such as plasma 40 depicted in FIG. 2a, in order to clean the surface of substrate 100 before ALD deposition commences. In this manner, each substrate may be precleaned in-situ before ALD film deposition. For substrate surfaces requiring oxidation, oxygen plasma may be provided, while for substrate surfaces requiring reduction, a hydrogen plasma may be provided. In further embodiments, pre-cleaning of the substrate 100 is performed by heating the substrate in addition to or instead of exposing the substrate to a plasma.

In some embodiments, rather than performing an ion assisted ALD process in two separate chambers, a single chamber, such as chamber 30, is used to introduce both the first and second reactant. In the first stage, a first reactant may be provided without the use of ions, while in the second stage, ions are provided to the substrate as described hereinabove.

In addition, processing of ALD films after film formation is performed in some embodiments. Thus, after reaction to form a reacted product layer 410, a substrate 100 may be subjected to additional processing, such exposure to ion flux, and annealing. The post-film formation processing may be used to improve film properties. For example, either annealing or ion bombardment or both may be performed to improve film density and remove unwanted species, such as hydrogen. The post-deposition processing may be performed in-situ while substrate 100 is located in chamber 30 or may be performed in another chamber or apparatus (not shown).

Although the aforementioned embodiments have been disclosed with reference in particular to the silicon nitride system, the present embodiments include systems and methods for ion-assisted ALD of other materials including SiC, SiCN, TiN, TaN, Ru, all of which may be deposited for use as etch stop or diffusion barriers, among other applications. Other materials covered by the present embodiments include metals, such as elemental metals that may be used for three dimensional metal gate applications, including in finFETs; oxide spacers, such as SiO₂; and other materials systems.

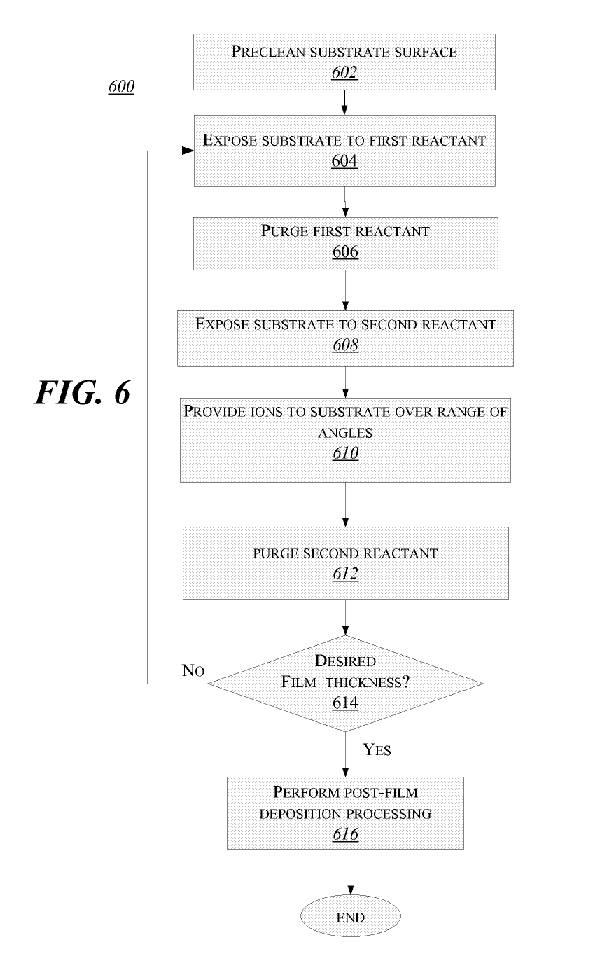

FIG. 6 depicts exemplary processes involved in a method 600 according to another embodiment. At block 602, a substrate is cleaned. Consistent with some embodiments, the cleaning may take place in-situ in an ALD system. The cleaning may involve exposure to ions and/or heating in some embodiments.

At block 604, the substrate is exposed to a first reactant. The first reactant may be a known material used for ALD processing, such as silane in the case of formation of silicon nitride. In some embodiments, the reactant is provided in a metered form to facilitate provision of an excess amount of reactant to a substrate, thereby ensuring formation of a monolayer of material on the substrate.

At block 606 the ambient surrounding the substrate is purged to flush out excess first reactant. At block 608, the substrate is exposed to a second reactant. The exposure to a second reactant may take place in a second chamber different from the chamber used to introduce the first reactant to the substrate. At block 610, the substrate is exposed to ion flux over a range of angles. The exposure to a second reactant and to angular ion flux may take place at the same time, or may partially overlap in time. Thus, referring also to FIG. 2b, a nitrogen-containing reactant may be provided toward a substrate 100 before a plasma is formed in chamber 30 or before a bias is applied to extract ions 108 toward substrate 100. When the plasma is ignited, the reactant may continue to be provided, and may also form at least a part of the ions. After the exposure to the second reactant and to the ion flux over a range of angles, a conformal product film may be formed.

At block 612, the second reactant is purged. At block 614, if a desired film thickness is not reached, the method returns to step 604. If a desired film thickness is reached, the process moves to block 616 where post-film deposition processing is performed. The processing may include exposure to ions and/or annealing of the substrate.

In summary, in various embodiments, a novel ALD system that provides ions distributed over a range of angles is presented, in which the operating parameters may be tailored to achieve a desired film conformality, film density, stress, and film composition.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings.

Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Thus, the claims set forth below should be construed in view of the full breadth and spirit of the present disclosure as described herein.

What is claimed is:

1. An apparatus for depositing a coating, comprising:
a first processing chamber configured to deposit a first reactant as a reactant layer on a substrate during a first time period; and
a second processing chamber configured to direct ions incident on the substrate over a range of angles, and configured to deposit a second reactant on the substrate during a second time period, said second reactant configured to react with said reactant layer.

2. The apparatus of claim 1, comprising a movable substrate holder arranged to scan the substrate between the first and second processing chambers over one of a linear path and an arc.

3. The apparatus of claim 1, wherein the first and second processing chambers are the same chamber.

4. The apparatus of claim 1, wherein the first time period is sufficient to saturate a first surface of the substrate with the first reactant and purge excess amounts of the first reactant from the first processing chamber after the surface is saturated with the first reactant; and wherein the second time period is sufficient to saturate the surface of the substrate having the first reactant with the second reactant and purge excess amounts of the second reactant from the first processing chamber after the surface is saturated with the second reactant.

5. The apparatus of claim 1, the second processing chamber comprising:
a region for forming a plasma; and
an extraction plate having an aperture configured to modify a shape of a plasma sheath of the plasma, wherein the aperture provides ions over the range of angles to the substrate.

6. The apparatus of claim 1, comprising a substrate heater configured to heat a substrate holder and thermally conduct said heat to said substrate.

7. The apparatus of claim 6, further comprising a plasma cleaning chamber, wherein the apparatus is configured to provide in-situ precleaning of the substrate using one or more of the substrate heater of the plasma cleaning chamber.

8. The apparatus of claim 1, comprising an isolator operable to isolate ambient of the first process chamber from ambient of the second process chamber.

9. The apparatus of claim 1, comprising a plasma source remote from said first processing chamber and said second processing chamber.

10. The apparatus of claim 1, wherein the second processing chamber is operable to vary the range of angles between a first range of angles comprising plus or minus sixty degrees centered on zero degrees and a second range of angles that is smaller than the first range.

11. A method of depositing a conformal film on a substrate, comprising:
depositing a first reactant as a reactant layer on the substrate at a first time;
reacting a second reactant on the reactant layer; and
exposing the reactant layer to ions that are incident on the substrate over a range of angles with respect to a plane of the substrate.

12. The method of claim 11, wherein depositing the first reactant further comprises saturating a surface of the substrate with the first reactant.

13. The method of claim 12, further comprising purging excess amounts of the first reactant before the condensing the second reactant.

14. The method of claim 11, further comprising:
providing the first reactant to the substrate from a first process chamber; and
providing the second reactant to the substrate from a second process chamber.

15. The method of claim 14, further comprising
providing a plasma in the second process chamber; and
extracting the ions from the plasma through an aperture in an extraction plate arranged to modify a shape of a plasma sheath of the plasma proximate the extraction plate.

16. The method of claim 15, comprising providing ions using a remote plasma source.

17. The method of claim 11, comprising heating the substrate during one or more of the depositing, reacting and exposing processes.

18. The method of claim 11, the depositing, reacting, and exposing steps each comprising a deposition cycle, the method further comprising repeating the deposition cycle a plurality of times.

19. The method of claim 14, comprising scanning the substrate from a first position proximate the first process chamber to a second position proximate the second process chamber between the depositing and the condensing step.

20. The method of claim 19, the depositing, reacting and exposing steps comprising a deposition cycle, the method further comprising:
repeating the deposition cycle a plurality of times; and
scanning the substrate from the second position to the first position between the condensing and the depositing step.
